(19) United States
(12) Patent Application Publication
(10) Pub. No.: US 2005/0023682 A1
(43) Pub. Date: Feb. 3, 2005

(54) High reliability chip scale package

(76) Inventor: Morio Nakao, Hiji-Machi (JP)

Correspondence Address: TEXAS INSTRUMENTS INCORPORATED, P O BOX 655474, M/S 3999, DALLAS, TX, 75265, US

(21) Appl. No.: 10/631,083

(22) Filed: Jul. 31, 2003

(51) Int. Cl. H01L 23/02; H01L 23/48; H01L 23/52; H01L 29/40

(52) U.S. Cl. 257/738; 257/787; 257/690

(57) ABSTRACT

A packaged chip-scale semiconductor device (400) has a substrate with a patterned metal layer (202) and first and second surfaces (202a and 202b, respectively). The first portion of an insulating material (305a) fills the spaces of the patterned metal layer. The second portion (401) of the insulating material is attached to the first surface (202a) of the patterned metal layer, forming a plurality of windows (402) to expose the metal for connection to external parts; around the periphery of these windows, the insulating material (401) preferably has a thickness of less than 30 μm. The third portion (205) of the insulating material forms, on the second surface (202b) of the patterned metal layer, a layer with an area suitable for attaching an integrated circuit chip (206). Solder balls attached to the metal surfaces exposed in the windows (402) have solder necks after reflow preferably less than 30 μm long, which helps avoid a solder separation problem induced by surface tension.

### FIELD OF THE INVENTION

The present invention is related in general to the field of semiconductor devices and more specifically to structures and fabrication methods of chip-scale packages with improved board-level reliability.

### DESCRIPTION OF THE RELATED ART

Several families of chip-scale devices, widely used in semiconductor technology, are based on the concept of a substrate which supports the integrated circuit chip on one side and the solder balls for board attach on the other side. This substrate is structured so that a metal layer is rolled onto a plastic carrier and patterned. On the chip side of the substrate, the chip contact pads are connected to the metal layer. On the solder ball side of the substrate, windows are opened into the plastic carrier to expose terminal pads of the metal pattern. The solder balls are attached to the metal exposed in those windows.

In this solder attachment process, the solder ball has to form a neck which fits into the window of the plastic carrier. This neck is the source of at least a couple of reliability problems. First of all, when the attached solder ball undergoes the solder reflow process for attaching the device to an external part such as a motherboard, the force of surface tension of the liquid spherical solder tends to pull the solder ball away from the solder neck in the carrier window. As a result, after cool-down and solidification, there is a risk of crack and separation between the neck, the device, and the ball attached to the board.

Secondly, the solder paste customarily employed in the attachment process frequently forms numerous small internal voids during the reflow process. These voids tend to remain in the hardened solder and amplify the risk of crack formation just described. Consequently, the effect of voids is especially pronounced in the long necks of the windows in conventional plastic carriers.

A need has therefore arisen for a coherent, low-cost method of highly reliable solder ball attachment. The fabrication method should be flexible enough to be applied for different semiconductor product families and a wide spectrum of design and process variations. Preferably, these innovations should be accomplished while shortening production cycle time and increasing throughput, and using the installed equipment base so that no investment in new manufacturing machines is needed.

### SUMMARY OF THE INVENTION

One embodiment of the invention is a substrate for a semiconductor package. The substrate has a sheet-like plastic carrier with first and second surfaces; a patterned metal layer removably attached to the first surface of the plastic carrier; and an insulating layer on the second surface of the plastic carrier.

Another embodiment of the invention is a packaged semiconductor device, which has a substrate, an integrated circuit chip, and plastic encapsulation material covering the chip. The substrate has a patterned metal layer with first and second surfaces and openings extending between these first and second surfaces; further a first insulating layer covering the first metal layer surface and extending into the openings such that the first insulating layer in the openings is coplanar with the second surface of the metal layer. A second insulating layer covers a portion of the second surface of the patterned metal layer and the openings. The second insulating layer preferably has a thickness less than about 30 μm; consequently, when solder balls are attached to the metal surfaces exposed in the openings of the second insulating layer, the solder necks after reflow are preferably less than 30 μm long, which helps avoid a solder separation problem induced by surface tension. The integrated circuit chip has active and passive surfaces; the passive surface is attached to the first insulating layer.

Another embodiment of the invention is a method for packaging an integrated circuit chip with active and passive surfaces and contact pads on its active surface. In this method, a substrate is provided which consists of a carrier tape; a patterned metal layer with first and second surfaces and openings extending between the surfaces, where the second surface is removably attached to the carrier tape; and a first insulating layer covering the first metal layer surface and portions of the carrier tape exposed in the openings of the patterned metal layer. The chip is attached to the first insulating layer on the substrate. The chip is encapsulated. Thereafter, the carrier tape is removed from the patterned metal layer to expose the second surface of the patterned metal layer. In an additional process step, the method applies a second insulating layer, preferably less than 30 μm thick, to the second surface of the patterned metal layer, whereby this second insulating layer covers a portion of the second surface of the patterned metal layer and leaves the second surface of the patterned metal layer exposed in windows in the second insulating layer. In a final process step, solder balls for connection to external parts are attached to the second surface of the patterned metal layer exposed in the windows in the second insulating layer.

Embodiments of the present invention are related to chip-scale and chip-size packages intended for reflow attachment to external parts such as mother-boards; other embodiments of the invention relate to packages in the ball grid array families. It is a technical advantage that the invention offers a control of the length of the solder ball neck and thus the effect of surface tension in liquid solder; solder breakage is avoided even for repeated solder reflows. Additional technical advantages derive from a variety of methods in the process step of removing the carrier tape from the patterned metal layer; the adhesive may be chosen so that brief exposures to infrared or ultra-violet radiation facilitate the removal process by additionally weakening the adhesive.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1A is a schematic cross section of a semiconductor package substrate as practiced in prior art.

FIG. 1B is a schematic cross section of a semiconductor package substrate according to an embodiment of the present invention.

FIGS. 2 to 4 show schematic cross sections of another embodiment of the invention, illustrating three stages in the fabrication process.

FIG. 2 depicts the device after completion of the encapsulation process.

FIG. 3 depicts the device after separation of the plastic carrier tape from the metal layer of the substrate.

FIG. 4 depicts the device after printing of the patterned insulating film, defining the windows for solder ball attachment.

FIG. 5 shows a schematic cross section of an additional step in the fabrication of the embodiment, the attachment of solder balls as interconnection elements to external parts.

### DETAILED DESCRIPTION OF THE PREFERRED EMBODIMENTS

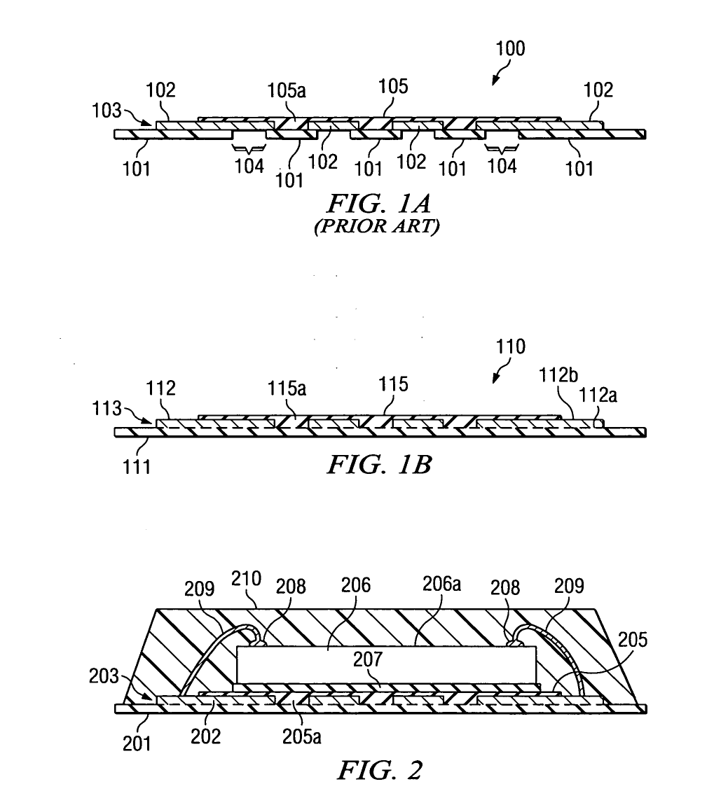

The schematic cross section of FIG. 1A illustrates a typical substrate, generally designated 100, as employed in known technology for chip-scale and chip-size devices. A metal layer 102 is joined with a sheet-like carrier 101, which is generally a plastic tape. The joining method is typically a roll-on process, which makes the two layers adhere to each other so strongly that they will not separate even under considerable force. In FIG. 1A, this strong adhesion between the two layers is indicated by a solid line 103. Thereafter, the metal layer 102 is patterned into conductive traces, and the plastic carrier tape 101 is patterned by windows 104 to expose metal areas, which serve to attach reflow interconnection elements such as solder balls. The metal layer 102 is covered by an insulating layer 105, which forms an area for attaching an integrated circuit (IC) chip. The insulating material also fills the spaces 105a of the metal pattern.

Because of the function which the substrate 100 fulfills in the known technology, the plastic carrier tape 101 typically has a thickness in the range from 50 to 100 μm. Consequently, the side walls in the windows 104, opened in carrier tape 101, have the same height, 50 to 100 μm. After solder balls have been attached in windows 104 and undergone a first reflow process, the windows 104 are filled with solder material. Thereafter, when the devices need to be attached to external parts such as printed mother boards, renewed melting of the solder balls is required. The surface tension of the newly melted solder tends to constrict the solder in the windows 104 with their high sidewalls away from the remaining solder, causing the probability of material separation after cool-down and solidification. In substantial numbers, the solder balls on the motherboard will end up detached from the device.

FIG. 1B illustrates an embodiment of the invention, a substrate, generally designated 110, for a semiconductor package as employed, for example, in chip-scale and chip-size devices. The substrate has a sheet-like plastic carrier 111 in the thickness range 30 to 80 μm. The tape is insensitive to elevated temperatures encountered in the process steps of chip mount curing (about 150 to 200° C.), wired bonding (about 175 to 250° C.), and transfer molding and curing (about 160 to 180° C.). Preferred tape material is a polyimide compound, as commercially available, for example, from Hitachi and Hitachi Chemical, both Japan.

A patterned metal layer 112 is attached to tape 111. The metal preferably is copper or a copper alloy in the thickness range from 10 to 35 μm. The attachment is by means of an adhesive weak enough to allow separation of plastic tape 111 from metal layer 112 at a later stage of the device fabrication, without damaging the patterned metal. In order to indicate symbolically the weakness of the attachment, the interface 113 is shown as a dashed line in FIG. 1B. As an example, a suitable, commercially available adhesive is Tomoegawa X, manufactured by Tomoegawa Company of Japan.

Substrate 110 in FIG. 1B further comprises an insulating layer 115, which covers the metal layer 112 and has an area sized for attaching an IC chip. The insulating material of layer 115 also fills the spaces 115a of the metal pattern. The preferred choice for insulating material 115 is a so-called solder resist, which is a modified photoresist and commercially available, for instance, from Taiyou Incorporated, Japan.

FIGS. 2 to 4 show schematic cross sections of another embodiment of the invention, a packaged chip-scale semiconductor device, in three stages of the fabrication process. In the fabrication stage of FIG. 2, the device has a substrate consisting of a carrier tape 201 and a patterned metal layer 202 attached to tape 201. Preferred material for tape 201 is a polyimide compound in the thickness range from 30 to 80 μm; preferred material for metal layer 202 is copper or a copper alloy in the thickness range 10 to 35 μm.

The attachment between tape 201 and metal layer 202 is weak, preferably accomplished by a material such as Tomoegawa X, commercially available from the Tomoegawa Company, Japan. In order to indicate the weakness of the attachment, interface 203 in FIG. 2 is shown as a dotted line. An insulating material, preferably solder resist, fills the spaces 205a of the metal pattern and forms a thin layer 205 over the metal layer 202, suitable in size for attaching the chip 206 by attach material 207 (typically a polymerizable epoxy) . The contact pads 208 of the active chip surface 206a are connected by wire bonds 209 to metal lands of metal layer 202. Chip 206 and wire bond 209 are protected by encapsulation material 210 (typically an epoxy-based molding compound).

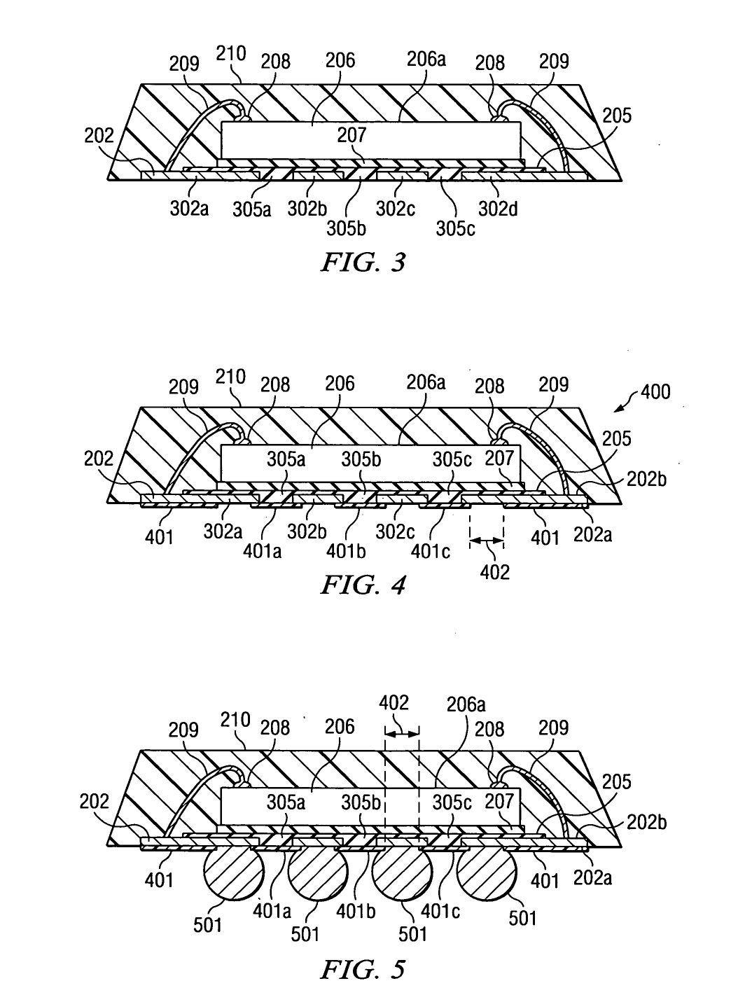

In FIG. 3, the embodiment is shown after completing the next process step. The carrier tape 201 of FIG. 2 has been removed, without damaging the patterned metal layer 202. The pattern of the metal layer, indicated in FIG. 3 by 302a, 302b, 302c, 302d, etc., is now exposed, together with the insulating material 305a, 305b, 305c, etc. The tape removal step may be a simple mechanical peeling of carrier tape 202, or it may be assisted by an at least brief exposure to infrared or ultra-violet radiation. This radiation helps to weaken the adhesive and facilitates the gentle removal of carrier tape 202. The time and energy of any radiation depends on the choice and thickness of the adhesive selected.

FIG. 4 illustrates the next process step of printing a film 401, preferably less than 30 μm thick, of the same solder-resist insulating material which is used for layer 205 and filling materials 305a, 305b, etc. on the patterned metal layer 202. This printing step is performed so that the film material merges with the insulator portions between the metal patterns; for instance, film portion 401a merges with filler portion 305a, film portion 401b merges with filler portion 305b, etc, and the metal of layer 202 is exposed in windows 402. The thickness of the insulating material surrounding each window 402 is preferably less than 30 μm. The semiconductor device after this process step is generally designated 400 in FIG. 4.

FIG. 5 depicts the process step of attaching solder balls to the metal in each window 402. Typically, the solder balls will undergo a first reflow process to reliably wet the metal of layer 202. In this reflow process, the window 402 is filled with liquid solder so that after cool-down and solidification, a solder neck less than 30 μm long is formed; the neck length equals the thickness of insulator 401. When the finished device of the embodiment in FIG. 5 has to undergo a second reflow process for board attach, the small amount of solder in the neck of less than 30 μm length does not exert enough force through surface tension to separate itself from the much more voluminous remainder of the solder ball. Consequently, a solder ball is much less likely to detach from device 400 during the board attach process.

Another embodiment of the invention is the method of fabricating a substrate for use in a semiconductor device having high reliability in device board attach. The substrate is illustrated schematically in FIG. 1B. Steps of this method are as follows: providing a sheet-like plastic carrier (111); providing a patterned metal layer (112) having first and second surfaces (112a and 112b respectively); applying a weak adhesive to attach the first metal surface (112a) to the plastic sheet (111), the adhesive being weak enough to allow separation of the plastic sheet (111) from the metal layer (112) without damaging the patterned metal; and depositing a layer (115) of insulating material over the second metal layer surface (112b) so that also the spaces (115a) of the metal pattern are filled with insulating material.

Another embodiment of the invention is the method of packaging an integrated circuit chip, which has an active surface with contact pads. The steps of this method, schematically shown in FIGS. 2 to 4, are as follows: providing a substrate comprising a carrier tape (201), a patterned metal layer (202) attached to the carrier tape by a weak adhesive, and insulating material filling the spaces (205a) of the metal pattern and forming a layer (205) over one surface of the metal layer; attaching the chip (206) to the insulating layer (205); wire bonding (209) the chip contact pads to the metal layer (202); encapsulating (210) the chip (206) and the bonding wires (209); removing the carrier tape (201) from the substrate without damaging the metal pattern (202), thereby exposing the patterned metal layer having the insulating material (205a) between the pattern. The removal of tape (201) may be facilitated by an at least brief exposure of the adhesive material to infrared or ultra-violet radiation; printing a film (401) less than 30 μm thick of the same insulating material on the patterned metal layer (202) so that the film material (401a) merges with the insulator portions (305a) between the metal pattern, leaving the metal pattern (202) exposed in windows (402). As an additional process step, illustrated in FIG. 5, solder balls (501) may be attached to the metal exposed in windows (402).

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the material of the semiconductor chip may comprise silicon, silicon germanium, gallium arsenide, or any other semiconductor or compound material used in IC manufacturing. It is therefore intended that the appended claims encompass any such modifications or embodiments.

1. A packaged semiconductor device, comprising:
a substrate, said substrate comprising:
a patterned metal layer having first and second surfaces and openings extending between said first and second surfaces;
a first insulating layer covering said first surface and extending into said openings such that said first insulating layer in said openings is coplanar with said second surface;
a second insulating layer covering a portion of said second surface of said patterned metal layer and said openings;
an integrated circuit chip having active and passive surfaces, said passive surface attached to said first insulating layer; and
plastic encapsulation material covering said chip.

2. The device according to claim 1, wherein said second insulating layer is solder resist.

3. The device according to claim 1, wherein said second insulating layer has a thickness less than about 30 μm.

4. The device according to claim 1, wherein said metal layer comprises copper and has a thickness in the range of 10 to 35 μm.

5. A substrate for a semiconductor package, comprising:
a sheet-like plastic carrier having first and second surfaces;
a patterned metal layer removably attached to said first surface of said plastic carrier; and
an insulating layer on said second surface of said plastic carrier.

6. The substrate according to claim 5, wherein said plastic carrier is a polyimide film having a thickness in the range of about 30 μm to 80 μm.

7. The substrate according to claim 5, wherein said metal layer comprises copper and has a thickness in the range of 10 to 35 μm.

8. The substrate according to claim 5, wherein said second insulating layer is solder resist.

9. The substrate according to claim 5, wherein said second insulating layer has a thickness less than about 30 μm.

10. A method for packaging an integrated circuit chip, said chip including active and passive surfaces with contact pads on said active surface, said method comprising the steps of:
providing a substrate, said substrate comprising:
a carrier tape;
a patterned metal layer having first and second surfaces and openings extending between said first and second surfaces, said second surface of said patterned metal layer removably attached to said carrier tape;
a first insulating layer covering said first surface of said patterned metal layer and portions of said carrier tape exposed in said openings in said patterned metal layer;
attaching said integrated circuit chip to said first insulating layer on said substrate;
encapsulating said chip; and
removing said carrier tape from said patterned metal layer to expose said second surface of said patterned metal layer.

11. The method according to claim 10, further comprising the step of:
applying a second insulating layer to said second surface of said patterned metal layer, said second insulating layer covering a portion of said second surface of said patterned metal layer and leaving said second surface of said patterned metal layer exposed in windows in said second insulating layer.

12. The method according to claim 11, further comprising the step of:
attaching solder balls to said second surface of said patterned metal layer exposed in said windows in said second insulating layer.

13. The method according to claim 10, wherein said step of removing said carrier tape is preceded by the step of exposing said carrier tape to infrared radiation.

14. The method according to claim 10, wherein said step of removing said carrier tape is preceded by the step of exposing said carrier tape to ultra-violet radiation.

15. The method according to claim 11, wherein said step of applying a second insulating layer comprises applying less than 30 μm of insulating layer to said second surface of said patterned metal layer.

16. The method according to claim 11, wherein said step of applying a second insulating layer comprises applying solder resist to said second surface of said patterned metal layer.

17. The method according to claim 10, wherein said step of providing a substrate with a first insulating layer comprises providing a substrate with a solder resist layer covering said first surface of said patterned metal layer.
